(19) United States
(12) Patent Application Publication
(10) Pub. No.: US 2018/0163299 A1
(43) Pub. Date: Jun. 14, 2018

(54) METHOD FOR CONNECTING GRAPHENE AND METAL COMPOUND ELECTRODES IN CARBON NANOTUBE DEVICE THROUGH CARBON-CARBON COVALENT BONDS

(71) Applicant: Huazhong University of Science and Technology, Wuhan (CN)

(72) Inventors: Wenli ZHOU, Wuhan (CN); Yu ZHU, Wuhan (CN); Changsheng CHEN, Wuhan (CN); Yunbo WANG, Wuhan (CN); Junxiong GAO, Wuhan (CN)

(21) Appl. No.: 15/484,134

(22) Filed: Apr. 11, 2017

(30) Foreign Application Priority Data
Dec. 9, 2016 (CN) 201611130639.7

(51) Int. Cl. C23C 16/26; C23C 16/02; C25D 13/02

(52) U.S. Cl. CPC C23C 16/26; C01B 31/0273; C01B 31/0453; B82Y 40/00; C23C 16/0209; C25D 13/02; C23C 16/0227

(57) ABSTRACT

A method for connecting graphene and metal compound electrodes in a carbon nanotube device through carbon-carbon covalent bonds, the method including: 1) providing a substrate, designing and preparing pre-patterned metal membrane electrodes on the substrate; 2) mixing carbon nanotubes with a volatile organic solvent to yield a dispersed suspension solution, disposing the carbon nanotube between the pre-patterned metal membrane electrodes in the dispersed suspension to allow two ends of the carbon nanotube to connect to the metal membrane electrodes, to form a carbon nanotube device; 3) annealing the carbon nanotube device under a mixture of nitrogen and argon, etching, by metal atoms, a part of carbon atoms at two ends of the carbon nanotube connected to the metal membrane electrodes to form notches; and 4) using hydrocarbon gas as a carbon source, and performing a chemical vapor deposition process.

### CROSS-REFERENCE TO RELATED APPLICATIONS

Pursuant to 35 U.S.C. § 119 and the Paris Convention Treaty, this application claims the benefit of Chinese Patent Application No. 201611130639.7 filed Dec. 9, 2016, the contents of which are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND OF THE INVENTION

### Field of the Invention

The invention relates to a method for connecting graphene and metal compound electrodes in a carbon nanotube device through carbon-carbon covalent bonds.

### Description of the Related Art

With high electron mobility, zero energy band gap, and similar lattice structure to the carbon nanotube, graphene is an ideal electrode for carbon nanotube devices. However, a Schottky barrier is formed at the interface between the graphene and the carbon nanotube, and the contact resistance is much larger than the self-resistance of the carbon nanotube. In addition, there is a physical gap at the atomic level between the graphene and the carbon nanotube, resulting in an additional barrier. Besides, the physical gap is easily affected by the working environment of the carbon nanotube devices, which leads to instabilities.

### SUMMARY OF THE INVENTION

In view of the above-described problems, it is one objective of the invention to provide a method for connecting graphene and metal compound electrodes in a carbon nanotube device through carbon-carbon covalent bonds. The method decreases the contact resistance between the carbon nanotube and the graphene electrodes, reduces the power loss of device, and allows the graphene to grow on a pre-patterned catalytic metal substrate, during which, no transfer or etching of graphene is necessitated, preventing the introduction of additional impurities.

To achieve the above objective, in accordance with one embodiment of the invention, there is provided a method for connecting graphene and metal compound electrodes in a carbon nanotube device through carbon-carbon covalent bonds. The method comprises:
1) providing a substrate, designing and preparing pre-patterned metal membrane electrodes on the substrate;
2) mixing carbon nanotubes with a volatile organic solvent to yield a dispersed suspension solution, disposing the carbon nanotubes between the pre-patterned metal membrane electrodes in the dispersed suspension solution to allow two ends of the carbon nanotube to connect to the metal membrane electrodes, to form a carbon nanotube device;
3) annealing the carbon nanotube device under a mixture of nitrogen and argon, etching, by metal atoms, a part of carbon atoms at two ends of the carbon nanotube connected to the metal membrane electrodes to form notches; and
4) employing a hydrocarbon gas being selected from the group consisting of methane, ethylene, and acetylene as a carbon source, and catalytically decomposing, using a chemical vapor deposition process, the carbon source into carbon free radicals by the metal atoms of the metal membrane electrodes of the carbon nanotube device, and adsorbing the carbon free radicals on surfaces of the metal membrane electrodes or dissolving the carbon free radicals in the metal membrane electrodes, nucleating the carbon free radicals with a saturated concentration to form carbon-carbon bonds and a graphene in the notches of the carbon nanotube, the two ends of the carbon nanotube and the graphene membrane being connected by covalent bonds.

In a class of this embodiment, the metal membrane electrodes have a thickness of between 200 nm and 1.64 μm and a width of between 0.5 and 5 μm; and an interval between the metal membrane electrodes is between 0.5 and 6 μm.

In a class of this embodiment, a material of the substrate in 1) is one selected from the group consisting of Si, SiO₂, SiO₂/Si, GaN, GaAs, SiC, and BN.

In a class of this embodiment, a material of the pre-patterned metal membrane electrode in 1) is a catalytic transition metal or an alloy thereof; and the catalytic transition metal comprises: nickel, copper, iron, cobalt, and platinum.

In a class of this embodiment, the metal membrane electrode is a copper/nickel double-layered metal membrane with an atom ratio of copper to nickel of between 90:10 and 60:40.

In a class of this embodiment, the volatile organic solvent in 2) is ethanol, and the dispersed suspension solution has a concentration of the carbon nanotube of between 0.0001 and 0.001 mg/mL.

In a class of this embodiment, the assembling of the carbon nanotube in 2) adopts dielectrophoresis technique or atomic force microscopy nanomanipulation possessing real-time force/visual feedback

In a class of this embodiment, before 2), the carbon nanotube is mixed with an oxidant comprising a concentrated sulfuric acid, a concentrated nitric acid, and hydrogen peroxide to open carbon rings at two ends of the carbon nanotube; and the openings are used to adhere to oxidant groups for modification. In the meanwhile, the groups contained in the oxidant are connected to the carbon atoms at the openings, i. e., groups comprising sulfonic acid groups, carboxyl groups, and hydroxyl groups are introduced to the openings, thus realizing the modifications of the two ends of the carbon nanotube. The two ends of the carbon nanotube have integrated carbon ring structures; a part of the carbons are oxidized by the oxidant to destroy the integrity of the carbon rings of the carbon nanotube to form the end openings. Because of the openings, the groups can be connected to the openings. “End opening” refers to carbon rings disposed at edges of two ends of the carbon nanotube. That the groups are connected to the end opening is the modification of the end opening.

In a class of this embodiment, a number and positions of the oxidant groups at end openings of the two ends of the carbon nanotube are regulated by changing the concentration of the oxidant and the mixing time to regulate a number of the covalent bonds, positions of carbon atoms of the covalent bonds, and a crystal orientation of the carbon atoms during the interconnection of the graphene and the two ends of the carbon nanotube in the chemical vapor deposition process.

In a class of this embodiment, in 3), the annealing is conducted at a temperature of between 700 and 1020° C. in the presence of the mixture of nitrogen and argon for between 0.5 and 5 hrs, and a flow ratio of nitrogen to argon is between 200:100 and 275:450 sccm (standard mL/min).

In a class of this embodiment, the flow ratio of nitrogen to argon is 200:450 sccm.

In a class of this embodiment, the growth of the graphene membranes in 4) is performed under a normal pressure at temperature of between 700 and 1020° C. in the presence of mixed gases of hydrogen, argon, and methane for between 10 and 15 min, and a flow ratio of hydrogen to argon to methane is between 200:100:2 and 275:450:4 sccm.

The metal membranes are patterned on the substrate, as catalytic substrates for the growth of the graphene, the metal membranes provide pre-pattern for the graphene. The pre-patterned metal membranes are used as electrodes to assemble the carbon nanotube so that the two ends of the carbon nanotube are connected to the metal membranes. During the annealing process, the two ends of the carbon nanotube are etched by the metal membranes to form notches. Thereafter, the carbon source gas is introduced and catalytically decomposed by the metal membrane electrodes, so that the graphene membranes grow in the defected positions at two ends of the carbon nanotube.

The patterned graphene membranes are used as the electrodes and are covalently connected to two ends of the carbon nanotube, thus, the covalent connection between the graphene and specific positions of the carbon nanotube, that is, the two ends of the carbon nanotube, which is different from the random connection between the graphene and the carbon nanotube in the prior art.

The invention aims at preparing interconnected electrodes of a carbon nanotube device by covalent bonds between the graphene and specific positions of a single or multiple carbon nanotubes and provides a non-transferring and pre-patterned interconnecting technique of a carbon nanotube device comprising the graphene/metal composite electrode within a plan, an axis of the carbon nanotube is in parallel to the plane of the graphene. Covalent bonds are formed between the graphene and the two ends of the carbon nanotube at the graphene/metal composite electrode, so that the current carriers are effectively transported from the graphene electrodes to the carbon nanotube and therefore the contact resistance between the carbon nanotube and the graphene electrodes is decreased.

Advantages of the method for connecting graphene and metal compound electrodes in a carbon nanotube device through carbon-carbon covalent bonds according to embodiments of the invention are summarized as follows:

The carbon-carbon covalent bonds are formed between the graphene and the two ends of the carbon nanotubes at the graphene/metal composite electrodes, and the current carriers are well transported between the graphene and the carbon nanotube. Thus, the contact resistance between the graphene and the carbon nanotube is reduced, the power loss of the device is reduced, and the good interconnection of the carbon nanotube device is realized. In the meanwhile, the graphene grows on the pre-patterned metal substrate, no transfer or etching is required, thus being a good solution for the interconnection of the carbon nanotube device.

### BRIEF DESCRIPTION OF THE DRAWINGS

The invention is described hereinbelow with reference to the accompanying drawings, in which:

FIG. 1 is a structure diagram of an interconnected structure of pre-patterned graphene/metal composite electrodes and a carbon nanotube in accordance with one embodiment of the invention; and

FIG. 2 is a flow chart illustrating a method for connecting graphene and metal compound electrodes in a carbon nanotube device through carbon-carbon covalent bonds in accordance with one embodiment of the invention.

In the drawings, the following numbers are used: 1. Substrate; 21-22. Metal electrode; 3. Carbon nanotube; and 41-42. Graphene.

### DETAILED DESCRIPTION OF THE EMBODIMENTS

For further illustrating the invention, experiments detailing a method for connecting graphene and metal compound electrodes in a carbon nanotube device through carbon-carbon covalent bonds are described below. It should be noted that the following examples are intended to describe and not to limit the invention.

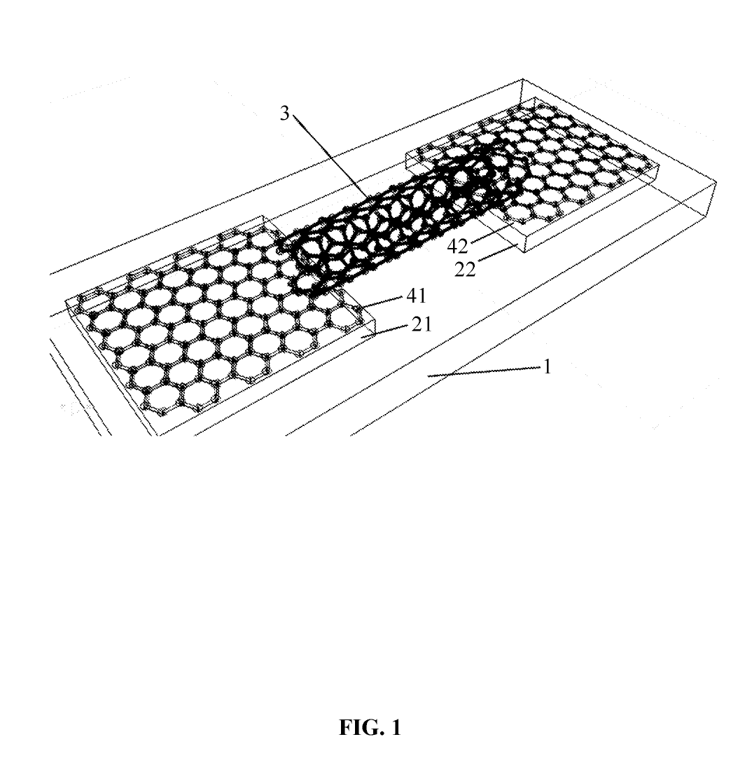

An interconnected structure of a carbon nanotube comprising a pre-patterned graphene/metal composite electrode is as shown in FIG. 1. A substrate 1 adopts high-temperature resistant material, and two metal membrane electrodes 21, 22 are formed on the substrate with an interval between the two electrodes of between 0.5 and 6 μm. A single or multiple of carbon nanotubes 3 are arranged between the two graphene electrodes 41, 42, and a length of each of the carbon nanotubes is larger than 0.5 The metal membranes 21, 22 are utilized as a catalyst, the CVD method is performed to allow the patterned graphene electrodes 41, 42 to grow and to form covalent connection with specific positions of the carbon nanotubes 3 contacting with the metal membrane electrodes, thus forming the interconnected structure.

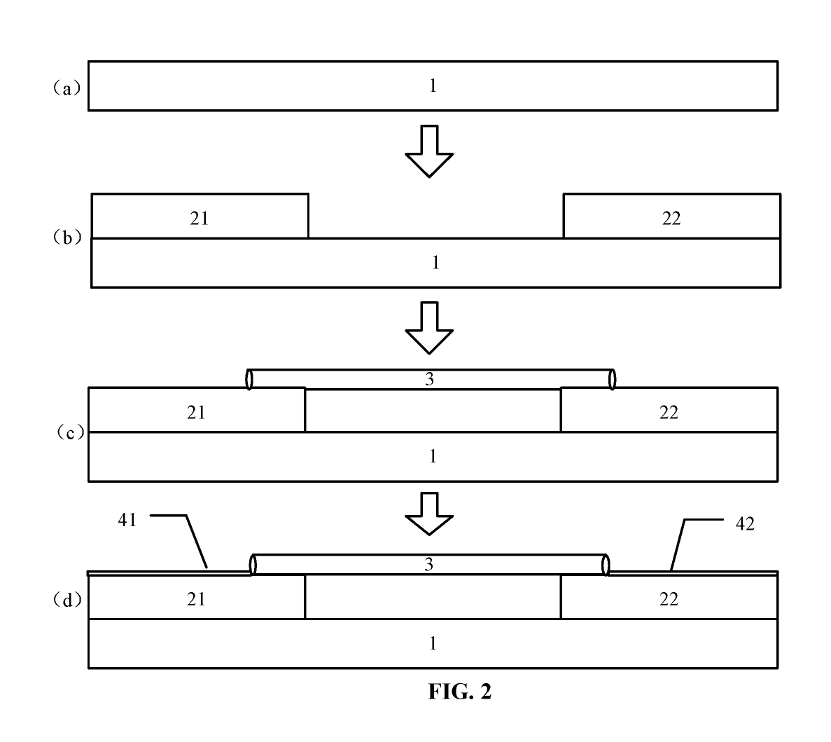

As shown in FIG. 2, a method for preparing interconnected structure between the pre-patterned graphene/metal composite electrode and the carbon nanotube is provided, and the method is conducted as follows:

1) A physical vapor deposition process and a photolithography process are adopted to prepare pre-patterned metal membrane electrodes on a surface of a substrate 1, as shown in FIG. 2 (a, b).

2) The carbon nanotubes and ethanol are mixed to prepare a dispersed suspension solution. Optionally, before the preparation of the dispersed suspension solution, the carbon nanotubes are mixed with a strong oxidant comprising a concentrated sulfuric acid, a concentrated nitric acid, and hydrogen peroxide to open carbon rings at two ends of the carbon nanotube. The openings are used to adhere to oxidant groups for modification.

3) The carbon nanotube 3 is assembled between the pre-patterned metal membranes 21, 22 using di electrophoresis technique or atomic force microscopy (AFM) nanomanipulation, to connect two ends of the carbon nanotube 3 to the metal membrane electrodes 21, 22, as shown in FIG. 2 (c).

4) Annealing treatment is then conducted in the presence of mixed gases of hydrogen and argon at a temperature of between 700 and 1020° C. for between 0.5 and 5 hrs to etch the two ends of the carbon nanotube connected to the metal membrane electrodes by metal atoms to form notches.

5) The carbon source gas is introduced, and graphene membranes 41, 42 are allowed to grow on the patterned copper-nickel electrodes via the CVD process, so that the carbon-carbon covalent interconnection of the carbon nanotube device comprising the pre-patterned graphene/metal composite electrodes is realized, as shown in FIG. 2 (d).

In the preparation of the interconnected structure between the pre-patterned graphene/metal composite electrodes and the carbon nanotube, the dielectrophoresis or the AFM manipulation for assembling the carbon nanotubes is prior art. The dispersed suspension solution comprising the carbon nanotube and ethanol (the volatile organic solvent) is adopted in assembling the carbon nanotube, and the parameters of the carbon nanotubes are selected according to the practical requirements of specific devices.

The dielectrophoresis technique requires using devices including pipettes and an AC signal generator. The AFM operation requires using the AFM.

The method for preparing the interconnected structure between the pre-patterned graphene/metal composite electrodes is explained in details combining with the drawings and the examples hereinbelow.

### Example 1

1) A silicon slice having an oxidant layer is utilized as a substrate. A nickel membrane having a thickness of 640 nm and a copper membrane having a thickness of 1 μm are respectively deposited on the substrate by magnetron sputtering, and an atom ratio of copper to nickel is 60:40.

2) The copper/nickel double-layered metal membranes are processed to form patterns using photolithography and chemical etching processes to yield a corresponding layout of interconnected electrodes of the carbon nanotube device. An interval between the electrodes is 6 μm, and a width of each of the electrodes is 5 μm.

3) A sinusoidal AC voltage with a frequency of 1 MHz and a peak value of 16 V is applied on the patterned copper/nickel electrodes, the dispersed suspension solution comprising carbon nanotube and ethanol with a concentration of the carbon nanotube of 0.001 mg/mL is collected by a pipette and dropped between the electrodes, and the externally applied electric field is removed after the solvent is evaporated.

4) The carbon nanotube device is annealed in the presence of mixed gases of hydrogen and argon for 5 hrs at a flow ratio of nitrogen to argon of 200:100 sccm, and then heated to 1020° C. Thereafter, mixed gases of hydrogen, argon, and methane are introduced at a normal pressure at a flow ratio of hydrogen to argon to methane of 200:100:2 sccm to allow the graphene membrane to grow for 15 min. The graphene membrane grows on the patterned catalytic substrate using the CVD process to realize the interconnection of the carbon-carbon covalent bonds of the carbon nanotube device comprising the pre-patterned graphene/metal composite electrodes.

### Example 2

1) A silica glass is used as a substrate and an inversed pattern of a catalytic substrate pattern is photolithographed on a surface of the substrate.

2) An electron beam evaporation process is adopted to deposit a nickel membrane having a thickness of 110 nm and a copper membrane having a thickness of 1 μm on the substrate, respectively, to make an atom ratio of copper to nickel at 90:10.

3) The substrate is displaced in acetone and treated by an ultrasonic wave for several minutes to remove a part of the copper/nickel membranes which is on the photoresist. A resulting substrate is disposed in ethanol and deionized water respectively for ultrasonic washing for 10 min, and then a patterned copper/nickel double-layered metal membrane is obtained by using the lift-off process to yield a corresponding electrode arrangement for the interconnection of the carbon nanotubes. An interval between the electrodes is 3 μm, and a width of each of the electrodes is 2 μm.

4) The dispersed suspension solution comprising carbon nanotubes and ethanol with a concentration of the carbon nanotube of 0.001 mg/mL is collected by a pipette and dropped between the electrodes. After the solvent is evaporated, the carbon nanotube is assembled between the electrodes by using an AFM probe.

5) The carbon nanotube device is annealed in the presence of mixed gases of hydrogen and argon for 0.5 hr at a flow ratio of nitrogen to argon of 275:450 sccm, and then heated to 1020° C. Thereafter, mixed gases of hydrogen, argon, and methane are introduced at a normal pressure at a flow ratio of hydrogen to argon to methane of 275:450:4 sccm to allow the graphene membrane to grow for 15 min. The graphene membrane grows on the patterned catalytic substrate using the CVD process to realize the interconnection of the carbon-carbon covalent bonds of the carbon nanotube device comprising the pre-patterned graphene/metal composite electrodes.

### Example 3

1) A silicon slice having an oxidant layer is utilized as a substrate. Nickel membranes having a thickness of 200 nm is deposited on the substrate by magnetron sputtering.

2) The nickel membranes are processed to form patterns using photolithography and chemical etching processes to yield a corresponding layout of interconnected electrodes of the carbon nanotube device. An interval between the electrodes is 0.5 μm, and a width of each of the electrodes is 0.5 μm.

3) A sinusoidal AC voltage with a frequency of 1 MHz and a peak value of 16 V is applied on the patterned copper/nickel electrodes, the dispersed suspension solution comprising carbon nanotube and ethanol with a concentration of the carbon nanotube of 0.0002 mg/mL is collected by a pipette and dropped between the electrodes, and the externally applied electric field is removed after the solvent is evaporated.

4) Mixed gases of hydrogen, argon, and methane are preheated at 750° C. at a flow ratio of hydrogen to argon to methane of 250:450:2 sccm and then introduced to the CVD growing region to allow the graphene membrane to grow at a normal pressure at 700° C. for 10 min. The graphene membrane grows on the patterned nickel membrane using the CVD process to realize the interconnection of the carbon-carbon covalent bonds of the carbon nanotube device comprising the pre-patterned graphene/metal composite electrodes.

### Example 4

1) SiC is used as a substrate and nickel membrane having a thickness of 200 nm is deposited on the substrate by magnetron sputtering.

2) The nickel membrane is processed to form a pattern using photolithography and chemical etching processes to yield a corresponding layout of interconnected electrodes of the carbon nanotube device. An interval between the electrodes is 6 μm, and a width of each of the electrodes is 5 μm.

3) The carbon nanotubes are mixed with a concentrated sulfuric acid, so that carbon rings at two ends of the carbon nanotube are destroyed by the concentrated sulfuric acid to form openings, and end openings at the two ends of the carbon nanotube are modified by sulfonic acid groups. A dispersed suspension solution comprising the carbon nanotube and ethanol is prepared, and a concentration of the carbon nanotube is controlled at 0.0001 mg/mL. A sinusoidal AC voltage with a frequency of 1 MHz and a peak value of 16 V is applied on the patterned nickel electrodes, the dispersed suspension solution comprising carbon nanotube and ethanol is collected by a pipette and dropped between the electrodes, and the externally applied electric field is removed after the solvent is evaporated.

4) The carbon nanotube device is heated to 1020° C., and mixed gases of hydrogen, argon, and methane are introduced at a flow ratio of hydrogen to argon to methane of 250:450:2 sccm to allow the graphene membrane to grow for 15 min. The graphene membrane grows on the patterned nickel membrane using the CVD process to realize the interconnection of the carbon-carbon covalent bonds of the carbon nanotube device comprising the pre-patterned graphene/metal composite electrodes.

### Example 5

1) SiC is used as a substrate and nickel membrane having a thickness of 200 nm is deposited on the substrate by magnetron sputtering.

2) The nickel membrane is processed to form a pattern using photolithography and chemical etching processes to yield a corresponding layout of interconnected electrodes of the carbon nanotube device. An interval between the electrodes is 3 μm, and a width of each of the electrodes is 2 μm.

3) The carbon nanotubes are mixed with a concentrated nitric acid, so that carbon rings at two ends of the carbon nanotube are destroyed by the concentrated nitric acid to form openings, and end openings at the two ends of the carbon nanotube are modified by carboxyl groups. A dispersed suspension solution comprising the carbon nanotube and ethanol is prepared, and a concentration of the carbon nanotube is controlled at 0.0001 mg/mL. A sinusoidal AC voltage with a frequency of 1 MHz and a peak value of 16 V is applied on the patterned nickel electrodes, the dispersed suspension solution comprising carbon nanotube and ethanol is collected by a pipette and dropped between the electrodes, and the externally applied electric field is removed after the solvent is evaporated.

4) The carbon nanotube device is heated to 1020° C., and mixed gases of hydrogen, argon, and methane are introduced at a flow ratio of hydrogen to argon to methane of 250:450:2 sccm to allow the graphene membrane to grow for 15 min. The graphene membrane grows on the patterned nickel membrane using the CVD process to realize the interconnection of the carbon-carbon covalent bonds of the carbon nanotube device comprising the pre-patterned graphene/metal composite electrodes.

### Example 6

1) SiC is used as a substrate and nickel membrane having a thickness of 200 nm is deposited on the substrate by magnetron sputtering.

2) The nickel membrane is processed to form a pattern using photolithography and chemical etching processes to yield a corresponding layout of interconnected electrodes of the carbon nanotube device. An interval between the electrodes is 3 μm, and a width of each of the electrodes is 2 μm.

3) The carbon nanotube is mixed with hydrogen peroxide, so that carbon rings at two ends of the carbon nanotube are destroyed by hydrogen peroxide to form openings, and end openings at the two ends of the carbon nanotube are modified by hydroxyl groups. A dispersed suspension solution comprising the carbon nanotube and ethanol is prepared, and a concentration of the carbon nanotube is controlled at 0.0001 mg/mL. A sinusoidal AC voltage with a frequency of 1 MHz and a peak value of 16 V is applied on the patterned nickel electrodes, the dispersed suspension solution comprising carbon nanotube and ethanol is collected by a pipette and dropped between the electrodes, and the externally applied electric field is removed after the solvent is evaporated.

4) The carbon nanotube device is heated to 1020° C., and mixed gases of hydrogen, argon, and methane are introduced at a flow ratio of hydrogen to argon to methane of 250:450:2 sccm to allow the graphene membrane to grow for 15 min. The graphene membrane grows on the patterned nickel membrane using the CVD process to realize the interconnection of the carbon-carbon covalent bonds of the carbon nanotube device comprising the pre-patterned graphene/metal composite electrodes.

The method for connecting graphene and metal compound electrodes in a carbon nanotube device through carbon-carbon covalent bonds is adapted to decrease the contact resistance between the carbon nanotube device and the electrodes for realizing good interconnection of the carbon nanotube devices. In the meanwhile, the growth of the graphene on the pre-patterned metal catalytic membrane avoids the transfer and etch of the graphene, and no additional graphene defects are resulted.

Unless otherwise indicated, the numerical ranges involved in the invention include the end values. While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A method for connecting graphene and metal compound electrodes in a carbon nanotube device through carbon-carbon covalent bonds, the method comprising:
1) providing a substrate, and designing and preparing pre-patterned metal membrane electrodes on the substrate;
2) mixing carbon nanotubes with a volatile organic solvent to yield a dispersed suspension solution, disposing the carbon nanotube between the pre-patterned metal membrane electrodes in the dispersed suspension to allow two ends of the carbon nanotube to connect to the metal membrane electrodes, to form a carbon nanotube device;
3) annealing the carbon nanotube device under a mixture of nitrogen and argon, etching, by metal atoms, a part of carbon atoms at two ends of the carbon nanotube connected to the metal membrane electrodes to form notches; and
4) employing a hydrocarbon gas being selected from the group consisting of methane, ethylene, and acetylene as a carbon source, and catalytically decomposing, using a chemical vapor deposition process, the carbon source into carbon free radicals by the metal atoms of the metal membrane electrodes of the carbon nanotube device, and adsorbing the carbon free radicals on surfaces of the metal membrane electrodes or dissolving the carbon free radicals in the metal membrane electrodes, nucleating the carbon free radicals with a saturated concentration to form carbon-carbon bonds and a graphene in the notches of the carbon nanotube, the two ends of the carbon nanotube and the graphene being connected by covalent bonds.

2. The method of claim 1, wherein the metal membrane electrodes have a thickness of between 200 nm and 1.64 μm and a width of between 0.5 and 5 μm; and an interval between the metal membrane electrodes is between 0.5 and 6 μm.

3. The method of claim 1, wherein the substrate is a heat-resisting material selected from the group consisting of Si, SiO₂, SiO₂/Si, GaN, GaAs, SiC, and BN.

4. The method of claim 2, wherein the substrate is a heat-resisting material selected from the group consisting of Si, SiO₂, SiO₂/Si, GaN, GaAs, SiC, and BN.

5. The method of claim 1, wherein a material of the pre-patterned metal membrane electrode in 1) is a catalytic transition metal or an alloy thereof; and the catalytic transition metal comprises: nickel, copper, iron, cobalt, and platinum.

6. The method of claim 2, wherein a material of the pre-patterned metal membrane electrode in 1) is a catalytic transition metal or an alloy thereof; and the catalytic transition metal comprises: nickel, copper, iron, cobalt, and platinum.

7. The method of claim 5, wherein the metal membrane electrode is a copper/nickel double-layered metal membrane having an atom ratio of copper to nickel of between 90:10 and 60:40.

8. The method of claim 6, wherein the metal membrane electrode is a copper/nickel double-layered metal membrane having an atom ratio of copper to nickel of between 90:10 and 60:40.

9. The method of claim 1, wherein the volatile organic solvent in 2) is ethanol, and the dispersed suspension solution has a concentration of the carbon nanotube of between 0.0001 and 0.001 mg/mL.

10. The method of claim 2, wherein the volatile organic solvent in 2) is ethanol, and the dispersed suspension solution has a concentration of the carbon nanotube of between 0.0001 and 0.001 mg/mL

11. The method of claim 1, wherein the carbon nanotube in 2) is disposed using dielectrophoresis technique or atomic force microscopy nanomanipulation possessing real-time force/visual feedback.

12. The method of claim 2, wherein the carbon nanotube in 2) is disposed using dielectrophoresis technique or atomic force microscopy nanomanipulation possessing real-time force/visual feedback

13. The method of claim 1, wherein before 2), the carbon nanotube is mixed with an oxidant comprising a concentrated sulfuric acid, a concentrated nitric acid, and hydrogen peroxide to open carbon rings at two ends of the carbon nanotube to form openings; and the openings are used to adhere to oxidant groups for modification.

14. The method of claim 2, wherein before 2), the carbon nanotube is mixed with an oxidant comprising a concentrated sulfuric acid, a concentrated nitric acid, and hydrogen peroxide to open carbon rings at two ends of the carbon nanotube to form openings; and the openings are used to adhere to oxidant groups for modification.

15. The method of claim 13, wherein a number and positions of the oxidant groups at end openings of the two ends of the carbon nanotube are regulated by changing the concentration of the oxidant and the mixing time to regulate a number of the covalent bonds, positions of carbon atoms of the covalent bonds, and a crystal orientation of the carbon atoms during the interconnection of the graphene and the two ends of the carbon nanotube in the chemical vapor deposition process.

16. The method of claim 14, wherein a number and positions of the oxidant groups at end openings of the two ends of the carbon nanotube are regulated by changing the concentration of the oxidant and the mixing time to regulate a number of the covalent bonds, positions of carbon atoms of the covalent bonds, and a crystal orientation of the carbon atoms during the interconnection of the graphene and the two ends of the carbon nanotube in the chemical vapor deposition process.

17. The method of claim 1, wherein in 3), the annealing is conducted at a temperature of between 700 and 1020° C. in the presence of the mixture of nitrogen and argon for between 0.5 and 5 hrs, and a flow ratio of nitrogen to argon is between 200:100 and 275:450 sccm (standard mL/min).

18. The method of claim 17, wherein the flow ratio of nitrogen to argon is 200:450 sccm.

19. The method of claim 1, wherein the growth of the graphene membranes in 4) is performed under a normal pressure at temperature of between 700 and 1020° C. in the presence of mixed gases of hydrogen, argon, and methane for between 10 and 15 min, and a flow ratio of hydrogen to argon to methane is between 200:100:2 and 275:450:4 sccm.
